(19) United States
(12) Patent Application Publication
(10) Pub. No.: US 2025/0105375 A1
(43) Pub. Date: Mar. 27, 2025

(54) BATTERY SYSTEM

(71) Applicant: TOYOTA JIDOSHA KABUSHIKI KAISHA, Toyota-shi (JP)

(72) Inventors: Hiroshi Yoshida, Anjo-shi (JP); Takashi Ogura, Seto-shi (JP); Yuki Sugo, Seto-shi (JP)

(73) Assignee: TOYOTA JIDOSHA KABUSHIKI KAISHA, Toyota-shi (JP)

(21) Appl. No.: 18/792,574

(22) Filed: Aug. 2, 2024

(30) Foreign Application Priority Data
Sep. 27, 2023 (JP) 2023-165905

(51) Int. Cl. H01M 10/42; G01R 31/3835; G01R 31/396; H01M 10/48; H02J 7/00

(52) U.S. Cl. CPC H01M 10/425; G01R 31/3835; G01R 31/396; H01M 10/482; H02J 7/0016; H01M 2010/4271; H01M 2220/20

(57) ABSTRACT

When the battery is externally charged, the maximum value of the voltage change amount of the unit cell is detected. For each unit cell, the current cumulative value for equalization is integrated during a period from when the maximum value is detected until the last unit cell detects the maximum value. Based on the current value for equalization of each unit cell, equalization processing for discharging from each unit cell is executed.

### CROSS-REFERENCE TO RELATED APPLICATION

This application claims priority to Japanese Patent Application No. 2023-165905 filed on Sep. 27, 2023, incorporated herein by reference in its entirety.

### BACKGROUND

### 1. Technical Field

The present disclosure relates to a battery system.

### 2. Description of Related Art

Japanese Unexamined Patent Application Publication No. 2014-167457 (JP 2014-167457 A) describes detecting a singularity which is a maximum value of voltage change amount of a secondary battery during charging and discharging, and estimating capacity of the secondary battery based on the singularity.

### SUMMARY

In JP 2014-167457 A, the capacity of secondary batteries (unit cells) making up a battery pack is estimated. In a battery pack in which the unit cells are connected in series, when the capacity of the unit cells decreases (capacity retention rate decreases) due to, for example, degradation or the like, and the state of charge (SOC) of the unit cells comes to vary, there is concern that there will be unit cells that will become overcharged.

An object of the present disclosure is to reduce SOC variance by estimating SOC variance of unit cells using a singularity which is a maximum value of voltage change amount, and performing equalization control.

A battery system of the present disclosure includes
a battery pack in which a plurality of unit cells is connected in series,
a control device, in which
the control device
detects a maximum value of a voltage change amount of the unit cells when the battery pack is being charged,
computes a current cumulative value that is a cumulative value of a charging current of the unit cells,
obtains, for each of the unit cells, the current cumulative value in a predetermined period from a time of detecting the maximum value, and
executes equalization processing in which each of the unit cells is discharged, based on the current cumulative value for each of the unit cells.

In each unit cell, the maximum value of the voltage change amount is detected at approximately the same remaining capacity (charge capacity). According to this configuration, the current cumulative value is calculated as the cumulative value of the charging current in the predetermined period from the time of detecting the maximum value for each unit cell. Accordingly, the current cumulative value of each unit cell corresponds to SOC variance of each unit cell. Discharge is performed from each unit cell based on this current cumulative value, and the equalization processing is executed. Thus, SOC variance can be reduced.

Preferably, in the battery system,
the predetermined period may be a period until the maximum value of all the unit cells is detected in a group of the unit cells in which the equalization processing is executed.

The equalization processing of the unit cells may be performed for each group (section) of the unit cells. For example, the equalization processing may be performed for each battery module (stack), or the equalization processing may be performed for the entire battery pack. Also, the equalization processing may be executed in units of the monitoring unit and the equalization circuit.

According to this configuration, the predetermined period is set to the period until the maximum value of all the unit cells is detected in the group of unit cells in which the equalization processing is executed. Thus, SOC variance of all the unit cells included in the group (section) can be reduced.

Preferably, in the battery system, each of the unit cells may possess a characteristic in that a plurality of the maximum values is present, and the control device may be configured to start computation of the current cumulative value from a time of detecting the maximum value that is present on a high voltage side in a voltage of each of the unit cells, out of a plurality of the maximum values.

According to this configuration, the calculation of the current cumulative value is started from the time of detecting the maximum value that is present on the high voltage side in the voltage of the unit cell, and accordingly SOC variance on the side close to full charge of the unit cell can be reduced, and the unit cell can be suitably suppressed from being overcharged.

Preferably, in the battery system, the control device may be configured to perform discharging from the unit cells of which the current cumulative value is no less than a set value, and execute the equalization processing.

According to this configuration, setting the setting value based on detection error of the maximum value or the like enables discharging from unit cells that do not require discharge to be suppressed.

Preferably, in the battery system,
the control device may be configured to
execute the equalization processing after charging of the battery pack ends, and
not execute the equalization processing, when the maximum value of all the unit cells is not detected in the group of the unit cells by when the charging of the battery pack ends.

In some cases, there are unit cells regarding which the maximum value cannot be detected due to noise, disturbance, or the like. According to this configuration, when the maximum value of all the unit cells is not detected in the group of unit cells by when the charging of the battery pack ends, the equalization processing is not executed. Thus, increase in the degree of SOC variance of unit cells in which the maximum value was not detected can be suppressed.

According to the present disclosure, SOC variance can be reduced by estimating SOC variance of the unit cell and performing equalization control by using a singularity that is a maximum value of the voltage change amount.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is an entire configuration diagram of an electrified vehicle in which a battery system according to the present embodiment is mounted;

FIG. 2 is a diagram illustrating an example of an equalization unit;

FIG. 3 is a diagram showing the relation between OCV and the remaining capacity in the unit cell (LFP unit cell) of the present embodiment;

FIG. 4 is a flow chart illustrating an exemplary equalization current integration process performed in ECU; and

FIG. 5 is a flow chart illustrating an exemplary equalization processing performed by ECU.

### DETAILED DESCRIPTION OF EMBODIMENTS

Hereinafter, embodiments of the present disclosure will be described in detail with reference to the drawings. In the drawings, the same or corresponding parts are denoted by the same reference numerals, and the description thereof will not be repeated.

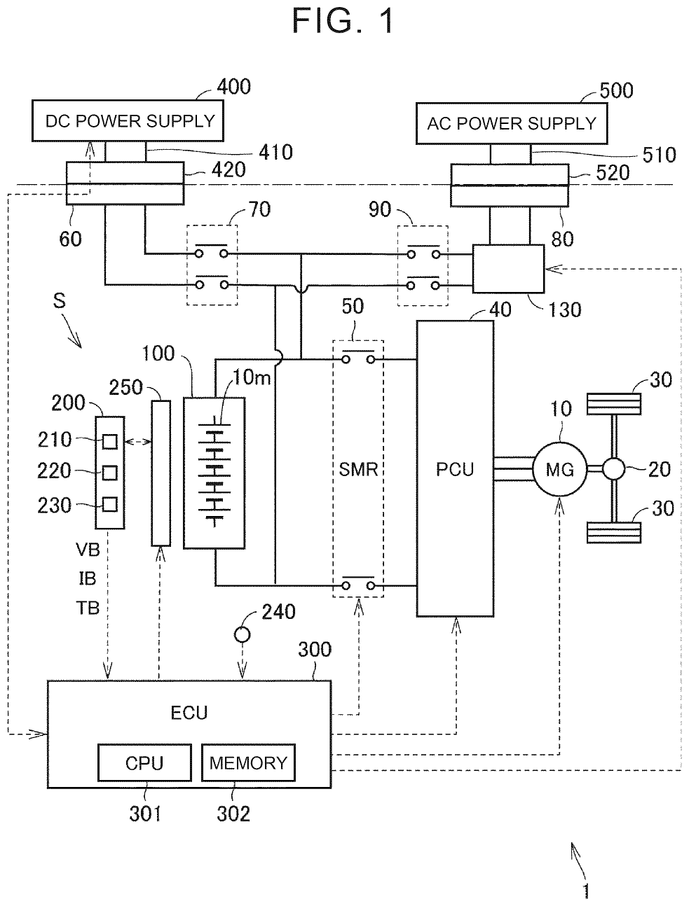

FIG. 1 is an entire configuration diagram of an electrified vehicle 1 in which a battery system S according to the present embodiment is mounted. In the present embodiment, electrified vehicle 1 is, for example, a battery electric vehicle. The electrified vehicle 1 includes a motor generator (MG) 10, a power transmission gear 20, a drive wheel 30, a power control unit (PCU) 40, a system main relay (SMR) 50, a battery 100, a monitoring unit 200, and an electronic control unit (ECU) 300 that is an exemplary control device.

MG 10 is, for example, an embedded-structure permanent-magnet synchronous motor (IPM motor), and has a function as an electric motor and a function as a generator. The output-torque of MG 10 is transmitted to the drive wheels 30 via the power transmission gear 20 including a speed reducer, a differential, and the like.

When electrified vehicle 1 is braked, MG 10 is driven by the drive wheels 30, and MG 10 operates as a generator. As a result, MG 10 also functions as a braking device that performs regenerative braking for converting kinetic energy of electrified vehicle 1 into electric power. The regenerative electric power generated by the regenerative braking force in MG 10 is stored in the battery 100.

PCU 40 is a power converter that bi-directionally converts power between MG 10 and the battery 100. PCU 40 includes, for example, inverters and converters that operate based on control signals from ECU 300.

When the battery 100 is discharged, the converter steps up voltage supplied from the battery 100 and supplies the stepped-up voltage to the inverter. The inverter converts DC power supplied from the converter into AC power to drive MG 10.

On the other hand, when the battery 100 is charged, the inverter converts AC power generated by MG 10 into DC power and supplies the DC power to the converter. The converter steps down voltage supplied from the inverter to voltage suitable for charging the battery 100 and supplies the stepped-down voltage to the battery 100.

SMR 50 is electrically connected to a power line connecting the battery 100 and PCU 40. If SMR 50 is ON (i.e., conductive) in response to a control signal from ECU 300, power may be transferred between the battery 100 and PCU 40. On the other hand, when SMR 50 is OFF (i.e., disconnected) in response to a control signal from ECU 300, the battery 100 is disconnected from PCU 40.

The battery 100 stores electric power for driving MG 10. The battery 100 is a DC power source (secondary battery) that can be recharged, and is a battery pack in which a plurality (M) of unit cells (battery unit cells) 10m (m is a positive integer from 1 to M) are stacked and electrically connected in series, for example. The unit cell 10m may comprise, for example, a lithium-ion unit cell. In the present embodiment, an iron phosphate lithium-ion battery (LFP battery) in which lithium iron phosphate is used as a positive electrode active material is employed as the unit cell 10m.

The monitoring unit 200 includes a voltage detection unit 210, a current sensor 220, and a temperature sensor 230. The voltage detection unit 210 detects the voltage VB of the unit cell 10m (the voltage VB between the terminals of the unit cell 10m). The current sensor 220 detects a current IB input to and output from the battery 100 (unit cell 10m). The temperature sensor 230 detects a temperature TB of each of the unit cell 10m. The detection unit outputs the detection result to ECU 300.

Electrified vehicle 1 includes a DC inlet 60, and the battery 100 can be rapidly charged from an external direct current (DC) power supply that is a charging facility. DC inlet 60 is configured to be connectable to a connector 420 provided at a distal end of the charging cable 410 of the external DC power supply (charging facility) 400. The charge relay 70 is electrically connected to a power line connecting DC inlet 60 and the battery 100. The charge relay 70 switches between supplying and shutting off power between DC inlet 60 and the battery 100 in response to a control signal from ECU 300. When the charge relay 70 is closed, external charging (quick charging) of the battery 100 is performed.

Electrified vehicle 1 includes a AC inlet 80, and the battery 100 can be normally charged from an external alternating current (AC) power supply, which is a charging facility. AC inlet 80 is configured to be connectable to a connector 520 provided at a distal end of the charging cable 510 of the external AC power supply (charging facility) 500. An in-vehicle charger 130 is provided in a power line between AC inlet 80 and the battery 100, and converts AC power supplied from an external AC power source into DC power and converts the battery 100 into a chargeable voltage. The charging relay 90 is electrically connected to a power line connecting the in-vehicle charger 130 and the battery 100. The charge relay 90 switches between supplying and shutting off the electric power between the in-vehicle charger 130 and the battery 100 in response to a control signal from ECU 300. When the charging relay 90 is closed, external charging (normal) of the battery 100 is performed.

ECU 300 includes Central Processing Unit (CPU) 301 and memory (e.g., Read Only Memory (ROM) and Random Access Memory (RAM) etc.) 302. The ECU 300 controls the devices so that electrified vehicle 1 is in a desired condition based on the signals received from the monitoring unit 200, the signals (e.g., throttle valve opening degree signals, vehicle speed signals, and the like) from the various sensors (not shown), the maps and programs stored in the memory 302, and the like. In addition, ECU 300 performs an equalization processing of the unit cell 10m by using an equalization unit (equalization circuit) 250. The battery system S includes a battery 100 (unit cell 10m), a monitoring unit 200, an equalization unit 250, an ECU 300, and the like.

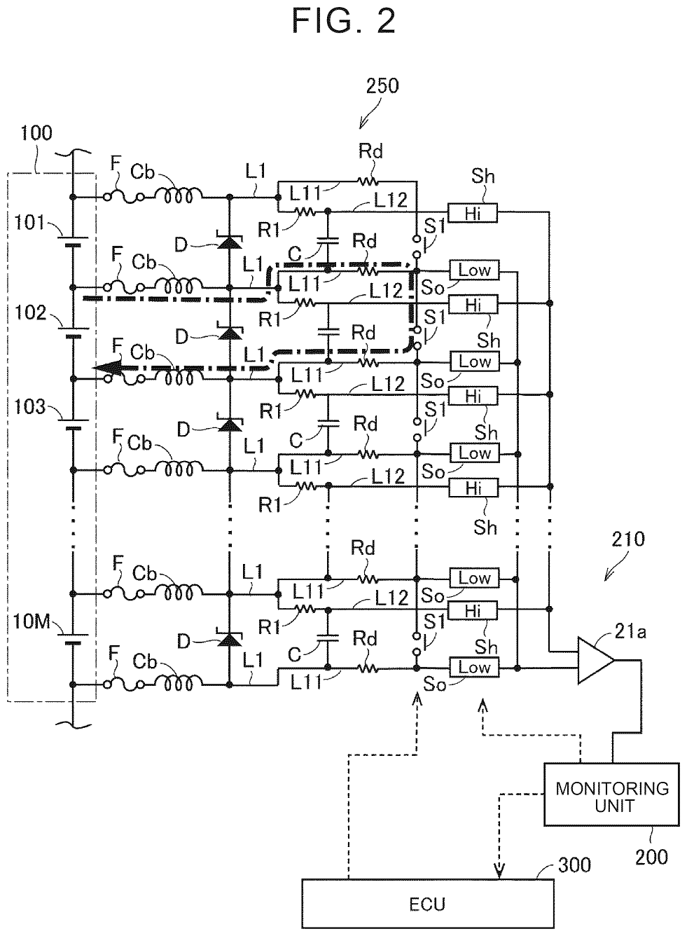

FIG. 2 is a diagram illustrating an example of the equalization unit 250. In the present embodiment, the equalization unit 250 is incorporated as an equalization circuit in the voltage detection unit (voltage detection circuit) 210 of the monitoring unit 200. In the battery 100, 10M are connected in series from a plurality of unit cells (battery unit cells) 101. The voltage detection unit 210 detects the voltage of 10M from the unit cell 101 via the plurality of voltage detection lines L1, the branch line L11, and the branch line L12. The voltage detection line L1 is connected to the positive electrode terminal of the unit cell 101 and the negative electrode terminal of the unit cell 10m. The voltage detection line L1 is connected between the unit cell 101 and 10M to the negative electrode terminal of one unit cell and the negative electrode terminal of the other unit cell.

A fuse F and a chip bead Cb are provided in the voltage detection line L1. The fuse F is blown when an overcurrent occurs to protect the circuit. The chip bead Cb reduces the applied stress when the surge-voltage is applied instantaneously.

A Zener diode D is connected in parallel to 10M from the unit cell 101 via a voltage detection line L1. The cathode of the Zener diode D is connected to the positive terminal side of the corresponding unit cell, and the anode is connected to the negative terminal side of the corresponding unit cell. When an overvoltage is applied from the battery 100 (unit cell 10m) to the voltage detection unit 210, a current flows through the Zener diode D to protect the voltage detection unit 210 from the overvoltage.

The voltage detection line L1 branches from the Zener diode D to the branch line L11 and the branch line L12 at the monitoring unit 200. The branch line L11 is connected to the comparator 21a via the switch So, and the branch line L12 is connected to the comparator 21a via the switch Sh. Switch So and switch Sh may use, for example, photo Metal Oxide Semiconductor (MOS) relays. The branch line L11 branched from the voltage detection line L1 connected to the positive electrode terminal of the unit cell 101 disposed on the positive electrode output terminal of the battery 100 is not connected to the comparator 21a. In addition, the voltage detection line L1 connected to the negative electrode terminal of the unit cell 10M disposed on the negative electrode-output terminal of the battery 100 does not include the branch line L12.

A resistor R1 is provided in the branch line L12. A capacitor (flying capacitor) C is provided between the branch line L12 connected to the positive electrode terminal of each unit cell and the branch line L11 connected to the negative electrode terminal. In the branch line L12, the capacitor C is connected between the resistor R1 and the switch Sh, and forms a RC low-pass filter by the resistor R1 and the capacitor C. Capacitor C is connected in parallel with 10M from the corresponding unit cell 101, charges of 10M are charged to capacitor C from the corresponding unit cell 101, and the voltage value of capacitor C is 10M equal to the voltage value from the corresponding unit cell 101. The switch Sh and the switch So corresponding to 10M are turned ON (closed) from the specific unit cell 101, so that the voltage (unit cell voltage) VB of 10M is outputted from the specific unit cell 101 by the comparator 21a. Thus, the monitoring unit 200 can sequentially switch the switch Sh and So corresponding to each unit cell 101 to 10M to ON, and thereby detect the voltage VB of each unit cell 101 to 10M using the voltage detection unit 210. Further, the voltage Vb of the battery 100 can be detected by turning ON (closing) the switch Sh of the unit cell 101 and the switch So connected to the negative electrode terminal of the unit cell 10M.

The equalization unit 250 includes a discharging resistor Rd provided in the branch line L11 and a switch S1 that conducts (closes)/disconnects (opens) between neighboring branch lines L11. The switch S1 is switched between ON (closed) and OFF (open) by receiving a control signal from ECU 300. In FIG. 2, arrows indicated by dashed-dotted lines indicate current flows when the equalization control is executed in order to eliminate unevenness in SOC of the unit cell 10m. SOC of the unit cell 102 is large, and the unit cell 102 is discharged to execute the equalization control. When SOC of the unit cell 102 is large, the switch S1 corresponding to the unit cell 102 is turned ON (closed). When the switch S1 corresponding to the unit cell 102 is turned ON (closed), the current discharged from the unit cell 102 is consumed by the discharging resistor Rd, Rd, and SOC of the unit cell 102 decreases, as indicated by a dashed-dotted arrow, so that the equalization of SOC is performed. In this way, equalization between the unit cell 10m of the battery 100 (battery pack) is performed.

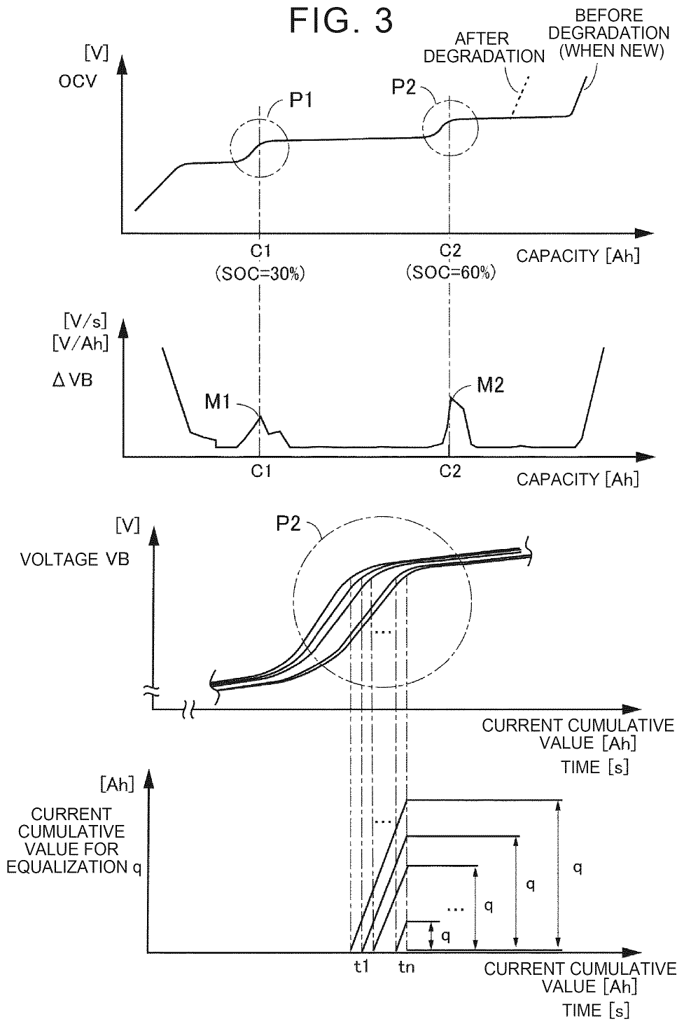

FIG. 3 is a diagram showing the relation between Open Circuit Voltage (OCV) and the remaining capacitance in the unit cell 10m (LFP unit cell) according to the present embodiment. In the first row of FIG. 3, the vertical axis represents OCV [V] of the unit cell 10m, and the horizontal axis represents the remaining capacity (charge capacity) [Ah] of the unit cell 10m. In the relation between OCV and the remaining capacitance (hereinafter, this relation is also referred to as a OCV curve), a region (voltage-flat region) in which the change of OCV curve is minute is widely present. When a portion where OCV curve is increased from the voltage flat region and becomes the voltage flat region again is referred to as a step, there are two step P1, P2 in the unit cell 10m of the present embodiment.

In the step P1 of the first stage (OCV is on the low-pressure side), SOC of the unit cell 10m at the time of a new product exists in the vicinity of about 30% (for example, the remaining capacity is C1). In the step P2 of the second stage (OCV is on the high-voltage side), SOC of the unit cell 10m at the time of a new product exists in the vicinity of about 60% (for example, the remaining capacity is C2). As shown by a broken line in the first row of FIG. 3, these steps do not change the position of the steps even when the full charge capacity of the unit cell 10m is reduced due to degradation of the unit cell 10m (when the capacity retention rate of the unit cell 10m is reduced). Even if the unit cell 10m deteriorates, the residual capacitance at which the step appears does not change.

The second stage of FIG. 3 shows the relationship between the voltage variation ΔVB of the voltage VB and the remaining capacity when the battery 100 is charged, and shows the relationship when the battery is charged with a constant current. The voltage change amount ΔVB is a change amount [V/Ah] of the voltage VB with respect to the remaining capacity (charge capacity) or a change amount [V/s] of the voltage VB with respect to the time (charge time). The voltage change amount ΔVB becomes the maximum value M1 in the remaining capacity C1 corresponding to the step P1, and becomes the maximum value M2 in the remaining capacity C2 corresponding to the step P2.

In a battery (battery pack) 100 in which unit cell 10m are connected in series, SOC of the unit cell 10m may gradually vary due to the progress of degradation, differences in temperature, differences in self-discharge rates, and the like. In a unit cell having a characteristic in which there is no voltage-flat area in OCV curve, SOC of the individual unit cells can be estimated by using SOC-OCV characteristic (SOC-OCV curve), and SOC variation of the individual unit cells can be eliminated. However, in the unit cell 10m according to the present embodiment, in a unit cell in which a voltage-flat area is present in OCV curve, it is difficult to determine SOC of the unit cell 10m based on SOC-OCV characteristic.

The third row of FIG. 3 shows the step P2 of the respective unit cell 10m at the time of external charge. The vertical axis represents the voltage VB [V] of the unit cell 10m, and the horizontal axis represents the cumulative value [Ah] of the charging current or the charging time [s]. When SOC of the individual unit cell 10m constituting the battery 100 are the same, the generation timing of the step P2 is substantially the same. When there is a variation in SOC of the unit cell 10m, P2 of steps in the unit cell 10m differs depending on the variation in SOC of the unit cell 10m. Therefore, in the present embodiment, the charge current is integrated from the time when the level difference P2 (maximum value M2) of the respective unit cell 10m is detected, and SOC variation between the unit cell 10m is estimated using the cumulative value.

In the present embodiment, as shown in the fourth stage of FIG. 3, the charge current is integrated from the time when the maximum value M2 (step P2) is detected for each unit cell 10m, and the current cumulative value q for equalization is calculated. The charge current is integrated until all the maximum value M2 of the unit cell 10m included in the battery 100 are detected, and the current cumulative value q for equalization is calculated. Finally, the charge current of the unit cell 10m in which the maximum value M2 is detected is not integrated, and the current cumulative value q for equalization of the unit cell 10m is 0 (zero). The variation in the current cumulative value q for equalization of the unit cell 10m corresponds to the variation in SOC of the unit cell 10m. t1 is the timing at which the maximum value M2 of the unit cell 10m is detected first. t2 is the timing at which the maximum value M2 of the unit cell 10m is finally detected (the timing at which all the maximum value M2 of the unit cell 10m included in the battery 100 are detected).

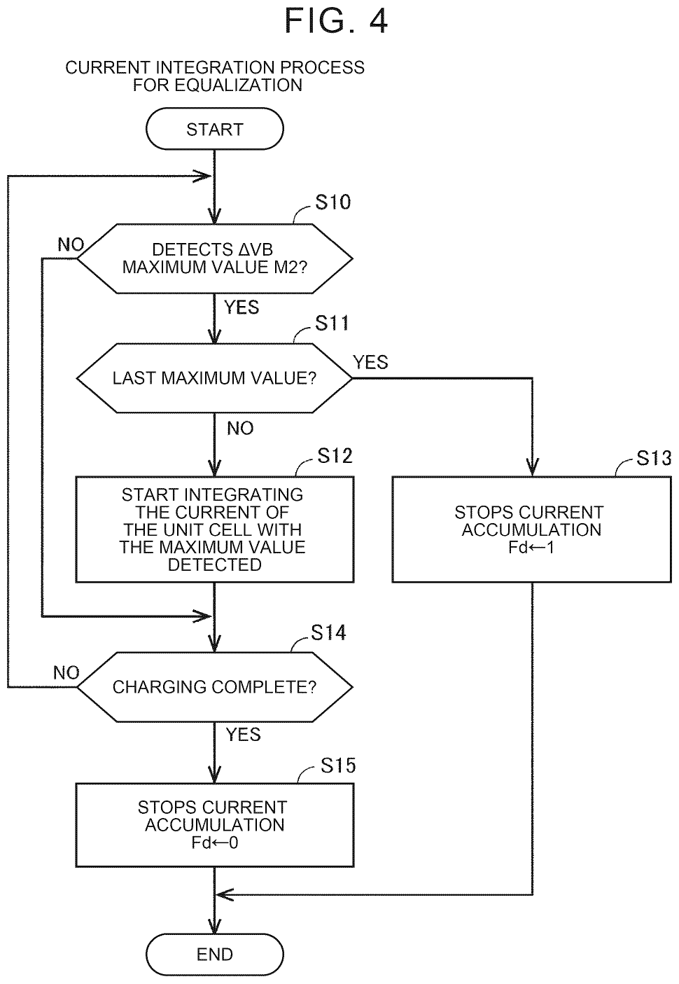

FIG. 4 is a flow chart illustrating an exemplary equalization current integration process performed by ECU 300. This flow chart is executed when external charging of the battery 100 is started, and is executed for each unit cell 10m. When the connector 420 is connected to DC inlet 60 or the connector 520 is connected to AC inlet 80 and the external charging of the battery 100 is started, ECU 300 determines whether or not the maximum value M2 of the voltage variation ΔVB of the voltage VB of the respective unit cell 10m is detected in the step (hereinafter, step is abbreviated as “S”) 10. The voltage change amount ΔVB may be a change amount [V/Ah] of the voltage VB with respect to the remaining capacity (charge capacity), and may be a change amount [V/s] of the voltage VB with respect to the time (charge time).

The maximum value of the voltage change amount ΔVB may be detected when the current voltage change amount ΔVB becomes a small value with respect to the previous voltage change amount ΔVB. Alternatively, the maximum value may be detected when the sign of the differential value of the voltage change amount ΔVB changes from positive to negative. The maximum value of the voltage variation ΔVB includes a maximum value M1 (step P1) on the low-pressure side and a maximum value M2 (step P2) on the high-pressure side. Therefore, when the voltage VB when the maximum value of the voltage variation ΔVB is detected is equal to or higher than the predetermined voltage, it may be determined that the maximum value M2 (the maximum value on the high voltage side) is detected. Alternatively, the integrated current threshold Qs may be obtained based on the voltage VB and the temperature TB at the time of starting the external charging, and after the cumulative value of the charging current exceeds the integrated current threshold Qs, the maximum value of the voltage variation ΔVB may be detected. Accordingly, it is possible to mask the detection of the maximum value M1 (the maximum value on the low-pressure side). Note that S10 process corresponds to an exemplary “maximum value detecting unit” of the present disclosure.

When the maximum value M2 of the voltage variation ΔVB of the unit cell 10m is detected, the process proceeds to S11, and when the maximum value M2 is not detected, the process proceeds to S14. In S11, it is determined whether or not the local maximum value M2 detected this time is the last local maximum value M2. When the maximum value M2 of all the unit cell 10m constituting the battery 100 is detected, it is determined that the last maximum value M2 is detected, and the process proceeds to S13. If the current maximum value M2 is not the last maximum value M2, the process proceeds to S12.

In S12, after the integration of the current cumulative value q for equalization of the unit cell 10m in which the maximum value M2 is detected is started, the process proceeds to S14. The integration of the current cumulative value q for equalization is performed by integrating the charging current detected by the current sensor 220. S12 process corresponds to an exemplary “current integrator” of the present disclosure.

In S14, it is determined whether or not the external charge of the battery 100 has been completed. When the battery 100 is fully charged, it may be determined that the external charging has ended. Further, it may be determined that the external charging is completed when the charging stopping operation is performed and the connector 420 is disconnected from DC inlet 60 or when the connector 520 is disconnected from AC inlet 80 prior to the full charging. If the external charge has not been completed, S10 returns. When the external charge is completed, the process proceeds to S15, the integration of the current cumulative value q for equalization is stopped, the flag Fd is set to 0, and then the present routine is ended. Here, the current cumulative value q for equalization of the individual unit cell 10m may be reset.

When the maximum value M2 of all the unit cell 10m constituting the battery 100 is detected until the external charge is completed, it is determined that the last maximum value M2 is detected in S11, and S13 proceeds. In S13, the integration of the current cumulative value q for equalization is stopped, the flag Fd is set to 1, and then the present routine is ended. Here, the current cumulative value q for equalization of the unit cell 10m is stored in the memory 302.

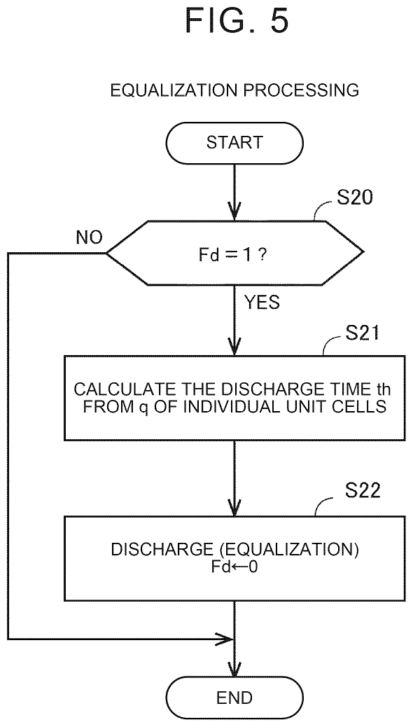

FIG. 5 is a flow chart illustrating an exemplary equalization processing performed by ECU 300. This flow chart is executed, for example, when IG switch (power switch) 240 is turned on. When IG switch 240 is turned on and the battery system S is activated, it is determined in S20 whether the flag Fd is 1. When S13 (FIG. 4) is processed and the flag Fd is set to 1, the process proceeds to S21. When the flag Fd is 0, a negative determination is made and the routine ends.

In S21, the discharging quantity of each unit cell 10m is calculated based on the current cumulative value q for equalization of each unit cell 10m. As shown in the fourth row of FIG. 3, the current cumulative value q for equalization of the respective unit cell 10m becomes larger as the unit cell 10m in which the maximum value M2 is detected earlier becomes larger, and finally, the current cumulative value q for equalization of the unit cell 10m in which the maximum value M2 is detected is 0. The discharging amount of each unit cell 10m may be a current cumulative value q for equalization of each unit cell 10m. In the present embodiment, the discharge time th of the individual unit cells 10m is calculated based on the current cumulative value q for equalization so that the current cumulative value q for equalization becomes 0 (zero).

In the following S23, the respective unit cell 10m are discharged (equalization processing), the flag Fd is set to 0, and the present routine is ended. The equalization processing is performed by performing discharge from each unit cell 10m by sequentially switching the switch S1 (see FIG. 2) corresponding to each unit cell 10m to ON (closing) during the discharge time th. As a result, variations in SOC of the individual unit cell 10m are reduced.

According to the present embodiment, the battery 100 is a battery pack in which unit cell 10m are connected in series. ECU 300 includes a maximum value detecting unit (S10) that detects a maximum value of the voltage change amount ΔVB of the unit cell 10m when the battery 100 is charged, and a current integrating unit (S12) that calculates a current cumulative value q for equalization, which is a cumulative value of the charging current of the unit cell 10m. ECU 300 obtains, for each unit cell 10m, an integrated current value q for equalization in a predetermined period from the time when the maximum value is detected, and performs an equalization processing of discharging from each unit cell 10m based on the current cumulative value q for equalization of each unit cell 10m. The current cumulative value q for equalization is calculated as the cumulative value of the charge current in a predetermined time interval from the time when the maximum value is detected for each unit cell 10m. Therefore, the current cumulative value q for equalization of each unit cell 10m corresponds to SOC variation of each unit cell 10m. On the basis of the current cumulative value q for equalization, discharging is performed from the respective unit cell 10m, and the equalization processing is executed. This can reduce SOC variation of the unit cell 10m.

In the above-described embodiment, the predetermined period is set to a period from when the maximum value of the unit cell 10m is detected until the maximum value of all the unit cell 10m included in the battery 100 is detected, and the current cumulative value q for equalization of the unit cell 10m is obtained. When the maximum value of all the unit cell 10m is not detected, the equalization processing is not executed. Therefore, since the single unit cell 10m in which the maximum value is not detected is not subjected to the equalization processing, it is possible to suppress an increase in SOC variation and to reduce SOC variation of all the single unit cell 10m included in the battery 100.

When a battery pack is configured by connecting a plurality of battery modules (stacks) in which a plurality of unit cells are connected in series and the battery pack is adopted as the battery 100, the equalization processing may be performed for each battery module, and the equalization processing may be performed for the entire battery pack. Further, the equalization processing may be performed for each unit of the monitoring unit 200 and the equalization unit 250. In this way, the group of unit cells to be subjected to the equalization processing may be arbitrarily selected.

In the above embodiment, since the calculation of the equalization current cumulative value q is started from the time of detecting the maximum value M2 present on the high-voltage side of the unit cell 10m, it is possible to reduce SOC variation in the side close to the full charge of the unit cell 10m, and the unit cell 10m can be well suppressed from being overcharged. However, after detecting the maximum value M1 present on the low-voltage side of the unit cell 10m, the calculation of the equalization current cumulative value q may be started, and the equalization processing may be executed using the equalization current cumulative value q.

In addition, a set value considering the accuracy of detecting the maximum value M2 or the like may be provided, and the equalization processing may be executed by discharging from the unit cell 10m in which the current cumulative value q for equalization is equal to or larger than the set value. As a result, unwanted discharging can be suppressed while reducing SOC variation.

In the above-described embodiment, an iron phosphate lithium-ion battery (LFP battery) is employed as the unit cell 10m. However, the unit cell 10m may be other types of unit cells as long as there is a small area (voltage flat area) in which the change in OCV curve is small and the maximum value of the voltage change amount ΔVB can be detected.

Vehicles to which the disclosed battery system S can be applied are not limited to electrified vehicle 1 shown in FIG. 1. The present disclosure is also applicable to, for example, a plug-in hybrid electric vehicle including an engine and a motor generator, and the present disclosure is also applicable to a fuel unit cell electric vehicle including a storage battery and capable of being externally charged. Alternatively, the vehicle may be an industrial vehicle such as a forklift. The battery system S may be a stationary battery.

The embodiment disclosed herein should be considered as illustrative and not restrictive in all respects. The scope of the present disclosure is defined not by the above description of the embodiments but by the claims, and is intended to include all possible modifications within a scope equivalent in meaning and scope to the claims.

What is claimed is:

1. A battery system, comprising:
a battery pack in which a plurality of unit cells is connected in series; and
a control device, wherein the control device
detects a maximum value of a voltage change amount of the unit cells when the battery pack is being charged,
computes a current cumulative value that is a cumulative value of a charging current of the unit cells,
obtains, for each of the unit cells, the current cumulative value in a predetermined period from a time of detecting the maximum value, and
executes equalization processing in which each of the unit cells is discharged, based on the current cumulative value for each of the unit cells.

2. The battery system according to claim 1, wherein the predetermined period is a period until the maximum value of all the unit cells is detected in a group of the unit cells in which the equalization processing is executed.

3. The battery system according to claim 1, wherein:
each of the unit cells possesses a characteristic in that a plurality of the maximum values is present; and
the control device is configured to start computation of the current cumulative value from a time of detecting the maximum value that is present on a high voltage side in a voltage of each of the unit cells, out of a plurality of the maximum values.

4. The battery system according to claim 3, wherein the control device is configured to perform discharging from the unit cells of which the current cumulative value is no less than a set value, and execute the equalization processing.

5. The battery system according to claim 2, wherein the control device is configured to
execute the equalization processing after charging of the battery pack ends, and
not execute the equalization processing, when the maximum value of all the unit cells is not detected in the group of the unit cells by when the charging of the battery pack ends.
